(19) United States
(12) Patent Application Publication
(10) Pub. No.: US 2012/0062398 A1
(43) Pub. Date: Mar. 15, 2012

(54) USE OF A ROTATING KNURLED WHEEL IN THE AUTOMOTIVE FIELD FOR MOVING AN ELEMENT IN TWO OPPOSITE DIRECTIONS

(75) Inventor: Eric Durand, Louveciennes (FR)

(73) Assignee: DURA AUTOMOTIVE SYSTEMS SAS, Bievres (FR)

(21) Appl. No.: 13/262,720

(22) PCT Filed: Mar. 26, 2010
(86) PCT No.: PCT/FR2010/050559

§ 371 Date: Dec. 2, 2011

(30) Foreign Application Priority Data
Apr. 3, 2009 (FR) 0952168

(51) Int. Cl. H03M 11/00

(52) U.S. Cl. 341/35

(57) ABSTRACT

A knurled wheel is subject to a mechanism capable of creating a system of detents. The knurled wheel is fitted with sensors for detection and selection, by processing of information about the speed of rotation of the knurled wheel, either of a step-by-step manual operating mode, in one or other direction of rotation of the wheel, or of an automatic continuous operating mode until an end-of-travel or stop position is reached, in one or other direction, or until an action is performed on the knurled wheel.

This invention relates to the technical sector of control means for moving an element, particularly in translation and in two opposite directions.

Application of this invention is particularly advantageous in the automotive field.

Using a device called a mouse is well known, particularly in the computer field, to move within a document displayed on the screen.

This mouse has a rotating knurled wheel to move, in particular towards the top or bottom of the document, depending on its direction of rotation and to scroll through the document displayed on the screen. Faster or slower rotation of the wheel by the user's finger concurrently enables faster or slower movement through the document.

Basically, in a way perfectly known to a person skilled in the art, the knurled wheel is fitted in combination with a toothed wheel enabling detents to be made linked to a blade or spring associated with a ball. For example, the number of detents can be 24 enabling, in a corresponding manner, a step-by-step movement of the knurled wheel in relation to a 48-slot toothed encoder wheel. Still in a known way and, by way of a non-limiting example, in order to convert the rotating mechanical movement of the knurled wheel into an electrical signal so as to ensure the desired control, in combination with the toothed encoder wheel, an infrared light-emitting diode is fitted together with phototransistors or other optical sensors enabling information to be provided about the knurled wheel's direction of rotation.

In the above example of 24 detents, the passage of one detent causes the knurled wheel to rotate through 15 degrees (360÷24). As the toothed wheel, still in the example given, has 48 detents, the passage of one detent therefore results in the passage of two slots.

Generally speaking, the effort required to pass one detent is calculated to prevent a passage of a detent when the user's finger is no longer in contact with the knurled wheel. Based on this design, in order to make the document scroll continuously, the knurled wheel must undergo a succession of rotations in one direction or the other by the user's finger. The movement achieved is nevertheless relatively slow.

In an attempt to remedy these drawbacks, a solution has been proposed that enables the knurled wheel to be operated by the user, by an inertia effect, so that the knurled wheel is freely rotated, escaping the action of the detents.

A solution of this type is disclosed, for example, in documents US 2007/0146311 and US 2007/0146324 which describe a mouse the knurled wheel of which can be rotated by a so-called step-by-step operation, depending on the number of detents, as indicated above, or freely by inertia, after pressing the finger on the said knurled wheel so as to escape the detents. This solution is relatively complex.

It is also observed that, after having operated the knurled wheel, by the effect of inertia, when said wheel stops, the action resulting therefrom also stops.

Based on this state of the art, the problem that the invention proposes to solve is to be able to ensure the control and movement of an element in two opposite directions, by means of a rotating knurled wheel with the aim of achieving a step-by-step movement or a continuous movement, even when the rotation of the knurled wheel has ceased.

Based on this technical problem, the invention covers the movement of different types of elements, including in the computer field, as is generally the case, but also in other fields such as the automotive field. In fact, the technical solution capable of solving this problem can be advantageously applied to operate windows or other similar devices, such as a privacy curtain, sliding door, sunroof, etc.

In order to solve such a problem, a control device has been designed and perfected to move an element in two opposite directions, the said device comprising a rotating knurled wheel subject to means capable of creating a system of detents, the said knurled wheel being fitted in combination with detection and selection means, either of a step-by-step manual operating mode, in one or other direction of rotation of the wheel, or of an automatic continuous operating mode until an end-of-travel or stop position is reached, in one or other direction, or until an action is performed on the said knurled wheel.

In a first embodiment, the detection and selection means of the different modes, by processing information on the speed of rotation of the said knurled wheel, are formed by sensors fitted in combination with the knurled wheel.

Thus, a speed of rotation greater than a threshold speed, between automatic mode and manual mode, hereinafter referred to as V_{AutoManualThreshold}, enables the mode to be changed and to pass into automatic mode. It may be advantageous to pass from a fine adjustment manual mode (slow mode) to a coarse adjustment manual mode (rapid mode). To this end, a new speed threshold V_{ManualRapidSlowThreshold} may be added. In this case, the distance of movement of the window depends on the number of steps of the knurled wheel, as well as on the speed of movement of the said wheel.

By way of a non-limiting example, a rotation by one detent of the knurled wheel in slow mode corresponds to a movement of the window of 5 mm, whereas a rotation by one detent of the knurled wheel in rapid mode corresponds to a movement of the window of 20 mm.

In another embodiment, the means of detecting and selecting the different modes are formed by sensors fitted in combination with the knurled wheel and capable of measuring its angular displacement, so that if the number of detents is less than a set threshold corresponding to the grip angle of the knurled wheel, the operation is of a manual type, whereas if the number of consecutive detents is more than the said threshold, the operation is of an automatic type.

These features, if applied to the operation of a vehicle window, make it possible not only to reproduce the functions generally obtained with a conventional commutator or switch but, also, to achieve greater precision, particularly in so-called manual operation.

It will be remembered, according to the state of the art, that a conventionally-operated vehicle-window switch usually has five monostable positions. Starting from a stable position in which no pressure or other action is exerted on the switch, either a simple push or pull pulse is exerted to lower or raise the window automatically to an end-of-travel stop position, or this pushing or pulling position is maintained to lower or raise the window manually until released. Difficulties can arise on moving the window in manual mode when the user desires a very limited and precise movement.

The technical solution at the heart of the invention enables these drawbacks to be remedied given that, in manual mode, it is possible to achieve a very precise step-by-step movement, in the order of a few millimetres, resulting from each of the detents of the knurled wheel.

Given the objectives to be achieved, the device is controlled by an algorithm to execute the manual and automatic operating modes, starting from a neutral so-called at-rest position, in which:
the manual mode of the element, in one or other direction of movement, is enabled
   if the number of detents detected is 1
   if the number of consecutive detents is lower than a threshold corresponding to a preset number of consecutive detents.
the automatic mode of the element, in one or other direction of movement, is enabled
   if the number of consecutive detents exceeds or is equal to a threshold corresponding to a preset number of consecutive detents.

In automatic or manual mode, a movement of the knurled wheel in the opposite direction to that of the element's movement causes the said movement to stop.

According to one embodiment, the knurled wheel is fitted in combination with sensors capable of selecting the different modes of manual or automatic operation by processing information on the speed of rotation of the said knurled wheel as well as the number of detents, so that a number of consecutive detents greater than a preset number of detents enables the mode to be changed and to pass to an automatic mode.

As indicated, the device may, in manual operating mode, be in a state in which a rotation by one detent of the knurled wheel corresponds to a slow movement of (x) mm and a state in which a rotation by one detent of the knurled wheel corresponds to a rapid movement of (x+n) mm. The distinction between slow manual mode and rapid manual mode being made on a preset threshold of the speed of rotation of the said knurled wheel, such a distinction is therefore made over a preset time between 2 steps of rotation.

By way of example, two detents are deemed to be consecutive if the time between these two detents is less than 100 milliseconds.

According to another feature and embodiment, the knurled wheel is subject to means for passing from a rotating action to square-wave signals in order to know the number of detents, its speed and its direction of rotation, the said signals being transmitted to a computer so as to control an actuator with a view to moving the element.

The knurled-wheel subjecting means comprise a photodiode, an encoder wheel and phototransistors of which the association of signals enables the direction of rotation of the knurled wheel to be known.

The computer comprises a microcontroller and a device to run a motor in two directions of rotation, said motor being associated with the actuator and fitted in combination with a reduction gear and Hall-effect sensors.

In order to solve the problem of obtaining continuous automatic operation in the embodiment in which the operating modes are detected on the basis of the number of consecutive detents, the knurled wheel is fitted rotatably in combination with devices capable of storing kinetic energy in order to overcome the detent effort and turn freely under a start-up effect.

Advantageously, to solve the problem of obtaining very high operating precision, the knurled wheel is mounted partially projecting beyond a support in combination with means capable of limiting the contact surface of the user's finger depending on the angular value of the opening angle of the said knurled wheel which corresponds to a set number of detents.

The invention is described below in greater detail with the aid of the accompanying drawings, in which:

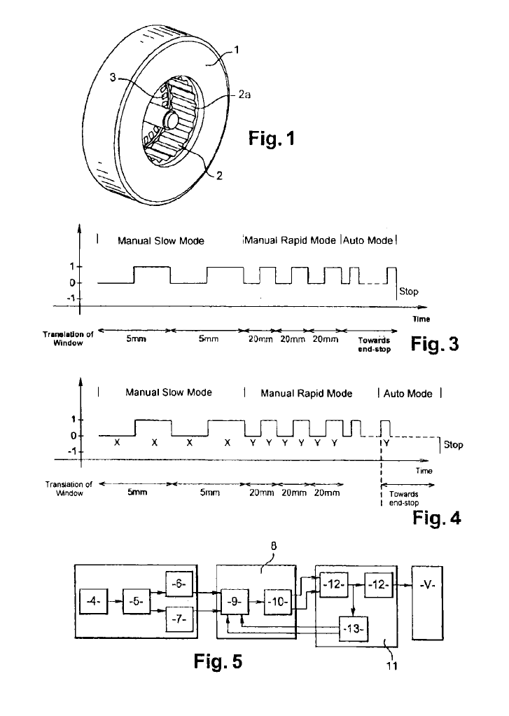

FIG. 1 is a perspective view of an embodiment of the knurled control wheel according to the invention;

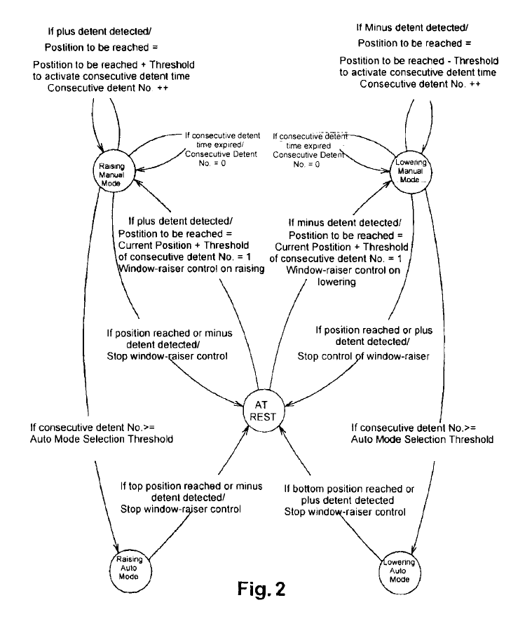

FIG. 2 is an example of a simplified state machine of the operation of the inertia knurled wheel according to the invention;

FIG. 3 is an example of a timeline relating to the translation control of the element in question, depending on the steps of the knurled wheel in conventional mode, that is, without inertia of the knurled wheel;

FIG. 4 is an example of a timeline relating to the translation control of the element in question, depending on the steps of the knurled wheel in inertia mode;

FIG. 5 is an operational block diagram illustrating how it is possible to pass from a rotating action on the wheel to electrical signals enabling the number of detents and the speed of rotation and direction of rotation to be known, in particular;

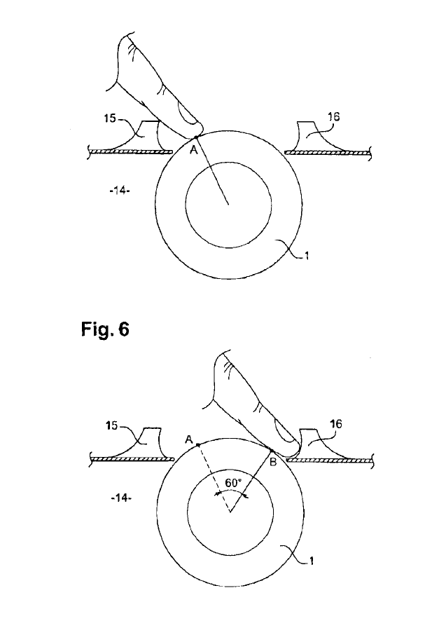

FIG. 6 is a schematic view of an advantageous installation of the knurled wheel, in order deliberately to limit the movement of the user's finger.

As indicated, the principle behind the control device according to the invention is the use of a rotating knurled wheel (1) having an internal toothed crown (2) presenting a number of detents (2a) regularly offset around the circumference and arranged facing an encoder wheel (3).

According to an important feature of the invention and in an advantageous embodiment, the knurled wheel (1) is subject to means capable of creating a system of detents for a step-by-step movement corresponding to a manual operation and to means capable of creating an inertia effect for a continuous movement corresponding to a so-called automatic operation.

In a manner perfectly know to a person skilled in the art, the phenomenon of rotational detent of the knurled wheel is achieved by a peak of effort opposed to its rotary movement. The possible angle of rotation of the knurled wheel is determined by a grip angle. The angular pitch of each detent being constant, the number of detents that can be passed in one rotation of the wheel is thus defined. Consequently, if the number of detents passed consecutively is greater than that thus defined, then the knurled wheel has turned through an angular value greater than the grip angle. To perform this function, the wheel must have been turned solely by the inertia of its element.

To achieve this goal, in the rotating part of the knurled wheel, sufficient energy should be stored in order to overcome the detent effort. The kinetic energy stored depends on the speed and mass of the knurled wheel.

Considering that the speed of the wheel is limited by the grip angle, the parameter that can be altered, in order to make the kinetic energy more than the said detent effort, is to increase the mass of the said wheel.

For example, after tests performed confidentially, advantageous results have been obtained if the knurled wheel has a mass of approximately 40 grams, bearing in mind that a traditional knurled wheel currently used in the field of computers, has a mass of approximately 3 grams.

In particular, this inertia effect can be obtained if the wheel has the following characteristics:
material, stainless steel
internal diameter, approximately 16 mm
external diameter, approximately 31 mm
thickness, approximately 8 mm
depth of detents, approximately 1 mm
spring diameter, approximately 0.5 mm.

Reference shall be made to the embodiment in FIG. 1.

Bearing these characteristics in mind, the knurled wheel (1) can therefore undergo a so-called normal or manual or step-by-step operation and a so-called by-inertia or automatic operation. Normal operation is performed at the maximum opening angle (or grip angle) of the knurled wheel corresponding to a preset number of detents and above which it is necessary to begin the movement again.

A pulling effort on the knurled wheel, linked with the inertia of the said knurled wheel, generates a greater angular rotation than the accessible angular sector of the said knurled wheel and, consequently, a greater number of steps resulting from the said by-inertia effect.

The knurled wheel can therefore perform two operations in the trigonometric direction and two operations in the clockwise direction, namely, for each direction, one normal rotation function and one by-inertia rotation function.

Thus, for example, for a continuous movement of less than 12 steps, in one direction or the other, the function to be selected will be normal, whereas for a continuous movement of more than 12 steps in one direction or the other, the function to be selected will be normal for the first twelve steps then, as from the 13th step, by inertia.

For a by-inertia application of the knurled wheel for the manual or automatic operation of raising or lowering of a window, the knurled wheel must enable the user to select, depending on the direction of rotation:
the manual raising or lowering of the window
the automatic raising or lowering of the window
to stop the manual raising or lowering of the window
to stop the automatic raising or lowering of the window.

In one embodiment, the means capable of differentiating the rotation of the knurled wheel corresponding to a normal operation from one corresponding to a by-inertia operation depends on the number of detents, that is, the number of “tops” performed by the knurled wheel without interruption.

In other words the manual raising or lowering of the window, for example, results from one rotation of the knurled wheel in one direction or the other, without detecting the rotation function of the said knurled wheel by inertia, while automatic raising or lowering results from one rotation of the knurled wheel by inertia in one direction or the other. Stopping manual raising or lowering results from reaching the end of the movement or from an action exerted on the said knurled wheel involving one or more detents, in the opposite direction to the movement in question, while stopping the automatic lowering or raising, also results from reaching the end of the movement (end-of-travel stop) or an action exerted on the said knurled wheel involving one or more detents, in the opposite direction to the movement in question.

Reference shall be made to FIG. 2, which shows a simplified state machine of the operation of the knurled wheel by inertia, and to the timeline shown in FIG. 4.

The at-rest state corresponds to a state where the knurled wheel is not manipulated and where the window is in a stable (stationary) state.

The manual raising mode corresponds to the state where the window manual raising mode is selected. In this state, the state machine must monitor the number of consecutive detents in order to pass, if necessary, into the auto-raising mode.

The auto-raising mode corresponds to the state where the automatic window-raising mode is selected.

The manual lowering mode corresponds to the manual window-lowering mode selected. In this state, the state machine must, just as for the raising mode, monitor the number of consecutive detents so as to pass, if necessary, into the auto-lowering mode.

The auto-lowering mode corresponds to the state in which the automatic window-lowering mode is selected.

Significantly, activating automatic mode (raising or lowering) enables the window to be raised or lowered until the top stop or bottom stop position is reached, when the knurled wheel is no longer rotated. In other words, the action performed in the knurled wheel's inertia mode continues, even when the said knurled wheel is no longer rotated.

This is not the case in the state of the art referred to in the introductory part of the description where the action caused by the rotation of the knurled wheel, including in so-called rapid mode, stops at the same time as the action of rotation of the said knurled wheel stops.

According to another embodiment, it is possible to use the information about the speed at which the user rotates the knurled wheel in order to select the different above-mentioned operating modes. In this embodiment, the knurled wheel is of a conventional type, that is, without inertia.

To this end, the knurled wheel is fitted in combination with sensors capable of selecting the different manual (normal) or automatic (inertia) operating modes by processing the information on the speed of rotation of the said knurled wheel.

Thus, a speed of rotation greater than the threshold speed, between automatic mode and manual mode, hereinafter referred to as V_{AutoManualThreshold}, allows the mode to be changed and to pass into automatic mode. It may be of advantage to pass from a fine adjustment manual mode (slow mode) to a coarse adjustment manual mode (rapid mode). To this end, a new speed threshold, V_{ManualRapidSlowThreshold}, may be added. In this case, the distance moved by the window depends on the number of steps of the knurled wheel, as well as the speed of movement of the said knurled wheel.

By way of a non-limiting example, a rotation by one detent of the knurled wheel in slow mode corresponds to a movement of the window of 5 mm, whereas a rotation by one detent of the knurled wheel in rapid mode corresponds to a movement of the window of 20 mm.

Reference is made to the operation timeline shown in FIG. 3.

In order to know the number of detents, speed of rotation and direction of rotation of the knurled wheel, the latter is subject to means to convert the rotation of the said knurled wheel into electrical square-wave signals.

For example, as shown in FIG. 5, the knurled wheel is subject to a photodiode (4), an encoder wheel (5) and two phototransistors (6) and (7), the association of which makes it possible to know the direction of rotation of the knurled wheel. The signals are transmitted to a computer (8) which comprises a microcontroller (9) and a device (10) to control the actuator in question (11) that is, in the example shown, the actuator controlling the raising or lowering of the windows (V).

More particularly, the power control device (10) acts on a motor reduction gear (12) of the actuator, in combination with two Hall-effect sensors (13).

Note that the signals at the output of the phototransistors (6)-(7) can be connected to capture inputs of the microcontroller (9).

These arrangements make it possible to operate on interruption (or event) and to memorize the time between the rising or lowering fronts via the timer of the capture inputs. These times will allow the speed of rotation of the knurled wheel to be known.

According to another characteristic of the invention, shown schematically in FIG. 6, the knurled wheel (1) is shown partially protruding from a support (14), in combination with means (15) and (16) capable of limiting the contact and movement surface of the user's finger depending on the angular value of the opening angle of the said knurled wheel which corresponds to a set number of steps. In fact, conventionally, under the effect of movement of the knurled wheel by the user's finger, this movement can be greater than the grip and opening angle of the said knurled wheel (90°), given that the user can use a large part of the contact surface of his finger, so that the angle of movement can, for example, be in the order of 110°. In other words, the number of detents or the number of steps generated by the opening angle of the knurled wheel can vary, which may affect the above-mentioned calculations.

End stops (15) and (16) arranged on either side of the contact surface of the user's finger delimited by the opening angle of the knurled wheel, limit the movements of the user's finger and, consequently, the operation of the knurled wheel by more than 90°.

In the diagrams shown in FIG. 6, the angle of rotation of the knurled wheel (1) is the angle delimited by the contact surfaces (A) and (B) of the finger and the centre of rotation of the knurled wheel, typically angle α of 60°.

The advantages clearly emerge from the description, emphasizing and recalling in particular:
the precision of movement of the knurled wheel obtained in manual mode, given that the latter can be of the step-by-step type and limited to one detent;
the operation at will of the manual step-by-step or automatic (inertia) mode, depending on the speed at which the knurled wheel is operated and/or on the number of detents detected;
the continuation in automatic mode of the movement in question, including when the action of rotation of the knurled wheel has ceased.
the advantageous application of the so-called by-inertia knurled wheel control device in the automotive field to operate windows, privacy blinds, sunroofs, a sliding door, etc.

1. A method of using a rotating knurled wheel in the automotive field for moving an element in two opposite directions, comprising: subjecting the knurled wheel to means capable of creating a system of detents, fitting the knurled wheel with sensors and detecting and selecting, by processing of information about speed of rotation of the knurled wheel, either a step-by-step manual operating mode, in one or other direction of rotation of the wheel, or an automatic continuous operating mode until an end-of-travel or stop position is reached, in one or other direction, or until an action is performed on the knurled wheel.

2-13. (canceled)

14. Method of using a rotating knurled wheel in the automotive field for moving an element in two opposite directions, comprising: subjecting the knurled wheel to means capable of creating a system of detents, fitting the knurled wheel with detection and selection means formed by sensors measuring wheel angular displacement, so that if number of detents is below a certain threshold corresponding to a grip angle of the knurled wheel, operation is manual, step-by-step, in one direction of operation of the knurled wheel or the other, whereas if the number of consecutive detents is above the threshold, the operation is automatic, continuous up to an end-of-travel or stop position, in one or other direction, or until an action is performed on the knurled wheel.

15. The method of using a rotating knurled wheel in the automotive field according to claim 14, wherein the element is controlled by an algorithm to execute manual and automatic operating modes, starting from a neutral at-rest position, in which:
the manual mode of the element, in one or other direction of movement, is enabled
if the number of detents detected is 1,
if the number of consecutive detents is lower than a threshold corresponding to a preset number of consecutive detents,
the automatic mode of the element, in one or other direction of movement, is enabled
if the number of consecutive detents exceeds or is equal to a threshold corresponding to a preset number of consecutive detents.

16. The method of using a rotating knurled wheel in the automotive field according to claim 1, wherein in automatic or manual mode, a movement of the knurled wheel in an opposite direction to that of the element's movement causes the element's movement to stop.

17. The method of using a rotating knurled wheel in the automotive field according to claim 1, wherein in manual operating mode, the knurled wheel may be in a state in which a rotation by one detent of the knurled wheel corresponds to a slow movement of (x) mm and a state in which a rotation by one detent of the knurled wheel corresponds to a rapid movement of (x+n) mm.

18. The method of using a rotating knurled wheel in the automotive field according to claim 1, wherein the knurled wheel is subject to means for passing from a rotating action to square-wave signals in order to know the number of detents, wheel speed and wheel direction of rotation, the signals being transmitted to a computer so as to control an actuator in order to move the element.

19. The method of using a rotating knurled wheel in the automotive field according to claim 18, wherein the means for passing comprise a photodiode, an encoder wheel and phototransistors which make known the direction of rotation of the knurled wheel.

20. The method of using a rotating knurled wheel in the automotive field according to claim 18, wherein the computer comprises a microcontroller and a device to control a motor in both directions of rotation of the actuator, the motor being fitted with a reduction gear and Hall-effect sensors.

21. The method of using a rotating knurled wheel in the automotive field according to claim 1, wherein the knurled wheel is fitted rotatably with devices storing kinetic energy in order to overcome a detent effort and turn freely under a start-up effect.

22. The method of using a rotating knurled wheel in the automotive field according to claim 1, wherein the knurled wheel is mounted partially protruding from a support, in combination with means limiting a contact surface of a user's finger depending on angular value of an opening angle of the knurled wheel which corresponds to a set number of detents.

23. The method of using a rotating knurled wheel in the automotive field according to claim 1, wherein the element movable in two opposite directions is a window particularly of a motor vehicle or another sliding part.

24. The method of using a rotating knurled wheel in the automotive field according to claim 1, wherein the element movable in two opposite directions is a door of a motor vehicle or another sliding part.
